(19) United States
(12) Patent Application Publication
(10) Pub. No.: US 2021/0167215 A1
(43) Pub. Date: Jun. 3, 2021

(54) THIN-FILM TRANSISTOR SUBSTRATE, METHOD FOR MANUFACTURING THE SAME, AND LIQUID CRYSTAL DISPLAY COMPRISING THE SAME

(71) Applicant: Mitsubishi Electric Corporation, Tokyo (JP)

(72) Inventors: Takeo FURUHATA, Tokyo (JP); Hiroya YAMARIN, Tokyo (JP)

(73) Assignee: Mitsubishi Electric Corporation, Tokyo (JP)

(21) Appl. No.: 17/048,104

(22) PCT Filed: Mar. 11, 2019
(86) PCT No.: PCT/JP2019/009650

§ 371 Date: Oct. 16, 2020

(30) Foreign Application Priority Data
Jun. 27, 2018 (JP) 2018-121605

(51) Int. Cl. H01L 29/786; H01L 27/12; H01L 21/02; H01L 29/66; G02F 1/1368

(52) U.S. Cl. CPC H01L 29/78606; H01L 27/1225; H01L 29/7869; H01L 21/0217; G02F 1/1368; H01L 27/127; H01L 27/1288; H01L 29/66969; H01L 21/02565

(57) ABSTRACT

The object is to provide a technology that can stabilize the characteristics of TFTs. A TFT substrate includes an oxide semiconductor layer, a source electrode and a drain electrode that are connected to the oxide semiconductor layer and separated from each other on the oxide semiconductor layer, and a SiN film covering a protective insulating film and containing hydrogen. The SiN film includes a first opening above at least a part of a first region of the oxide semiconductor layer between the source electrode and the drain electrode in a plan view.

### TECHNICAL FIELD

The present invention relates to a thin-film transistor substrate, a method for manufacturing the thin-film transistor substrate, and a liquid crystal display including the thin-film transistor substrate.

### BACKGROUND ART

Liquid crystal displays (LCDs), which are one type of conventional common thin panels, have widely been used for monitors of personal computers or portable information terminals by taking advantages of their low power consumption, small size, and light weight. In recent years, the liquid crystal displays have widely been used for TVs and others. To address problems in the liquid crystal displays such as a wide viewing angle, limitation in contrast, and a difficulty in following a high-speed response for moving images, electroluminescence (EL) displays including luminous elements such as EL elements as pixel units have also been used as next-generation thin panel devices. The EL elements are self-luminous, and have features including the wide viewing angle, high contrast, and the high-speed response unlike those of the liquid crystal displays.

Thin film transistors (hereinafter referred to as “TFTs”) included in these displays often use a metal-oxide-semiconductor (MOS) structure including a semiconductor layer as a channel layer (an active layer). The types of the TFTs with the MOS structure include an inverted staggered structure (a bottom gate structure) and a top gate structure. For example, an amorphous Si film or a polycrystalline Si film is used in the semiconductor layer as the channel layer. For example, small display panels often use the polycrystalline Si film to increase an aperture ratio of a display region and a resolution, and in view of a requirement to include the TFTs in a drive circuit unit such as a gate driver. However, in recent years, an InGaZnO-based oxide semiconductor layer which has higher mobility than amorphous silicon and which can be deposited at low temperatures has increasingly been used as a channel layer of the TFT.

In many cases, the TFTs used in a display are formed on a transparent substrate such as a glass substrate, and used while constantly receiving light from a backlight. A white light emitting diode (LED) is generally used as the backlight in such a display. The emission spectrum of the white LED is sharply peaked near a wavelength of 450 nm. The InGaZnO-based oxide semiconductor layer has an energy band gap of, for example, approximately 3.1 eV. Thus, the layer is transparent to visible light. However, the energy band has a level in which carriers are generated by excitation of the light near the wavelength of 450 nm. Thus, application of a negative voltage to gates under light emission creates a problem of characteristic variation or characteristic fluctuation in the TFTs.

Further, in a structure where pixel TFTs and drive circuit TFTs are disposed on the same glass substrate, the voltage stresses applied to the TFTs differ between the pixel unit and the drive circuit unit. Thus, the problem lies in the difficulty in simultaneously suppressing the characteristic fluctuations in the pixel TFTs and the peripheral drive circuit TFTs. To suppress the characteristic fluctuation in the TFTs, for example, in the technology of Patent Document 1, disposition of a conductive layer on a protective insulating film only in each of the drive circuit TFTs adjusts the threshold voltage and stabilizes the electrical characteristics of the drive circuit TFTs.

### PRIOR ART DOCUMENT

### Patent Document

[Patent Document 1] Japanese Patent Application Laid-Open No. 2011-54946

### SUMMARY

### Problem to be Solved by the Invention

However, the conventional technology has a problem, for example, the difficulty in suppressing the characteristic fluctuation in the pixel TFTs. Particularly, in a structure including a SiN film containing hydrogen for stabilizing the characteristics of a gate insulating film, the hydrogen causes a problem of fluctuation in the characteristics of the pixel TFTs, etc.

The present invention has been conceived in view of the problems, and has an object of providing a technology that can stabilize the characteristics of the TFTs.

### Means to Solve the Problem

A thin-film transistor substrate according to the present invention includes: a substrate; a first gate electrode selectively disposed on the substrate; a first gate insulating film covering the first gate electrode; a first oxide semiconductor layer disposed on the first gate insulating film and superposed on the first gate electrode in a plan view; a first source electrode and a first drain electrode that are connected to the first oxide semiconductor layer and separated from each other on the first oxide semiconductor layer; a first protective insulating film covering the first oxide semiconductor layer, the first source electrode, and the first drain electrode; and a first SiN film covering the first protective insulating film and containing hydrogen, wherein the first SiN film includes a first opening disposed above at least a part of a first region of the first oxide semiconductor layer between the first source electrode and the first drain electrode in the plan view.

### Effects of the Invention

The first SiN film according to the present invention includes the first opening disposed above at least the part of the first region of the first oxide semiconductor layer between the first source electrode and the first drain electrode in the plan view. Such a structure can stabilize the characteristics of the TFTs.

The object, features, aspects and advantages of the present invention will become more apparent from the following detailed description and the accompanying drawings.

### BRIEF DESCRIPTION OF DRAWINGS

FIG. 1 is a plan view schematically illustrating the entire structure of a relevant TFT substrate.

FIG. 2 is a cross section illustrating one example structure of a liquid crystal display including a TFT substrate.

FIG. 3 is a plan view schematically illustrating another entire structure of the relevant TFT substrate.

FIG. 4 is a plan view illustrating a structure of a TFT substrate according to Embodiment 1.

FIG. 5 is a cross section illustrating the TFT substrate according to Embodiment 1.

FIG. 6 is a plan view illustrating a part of a structure of the TFT substrate according to Embodiment 1.

FIG. 7 illustrates the Id-Vg characteristics of the TFTs before and after application of the stress according to Embodiment 1.

FIG. 8 is a cross section illustrating another structure of the TFT substrate according to Embodiment 1.

FIG. 9 is a cross section illustrating a structure of the TFT substrate according to Embodiment 1.

FIG. 10 is a flowchart illustrating a method for manufacturing the TFT substrate according to Embodiment 1.

FIG. 11 is a plan view illustrating a structure of a TFT substrate according to Embodiment 2.

FIG. 12 is a cross section illustrating the structure of the TFT substrate according to Embodiment 2.

FIG. 13 is a cross section illustrating a structure of a TFT substrate according to Embodiment 3.

FIG. 14 is a cross section illustrating a structure of a TFT substrate according to Embodiment 4.

FIG. 15 is a cross section illustrating a structure of a TFT substrate according to Embodiment 5.

### DESCRIPTION OF EMBODIMENTS

[Relevant Thin-Film Transistor Substrate]

Before describing a thin-film transistor substrate according to Embodiments of the present invention, a thin-film transistor substrate relevant to this (hereinafter referred to as a “relevant TFT substrate”) will be described.

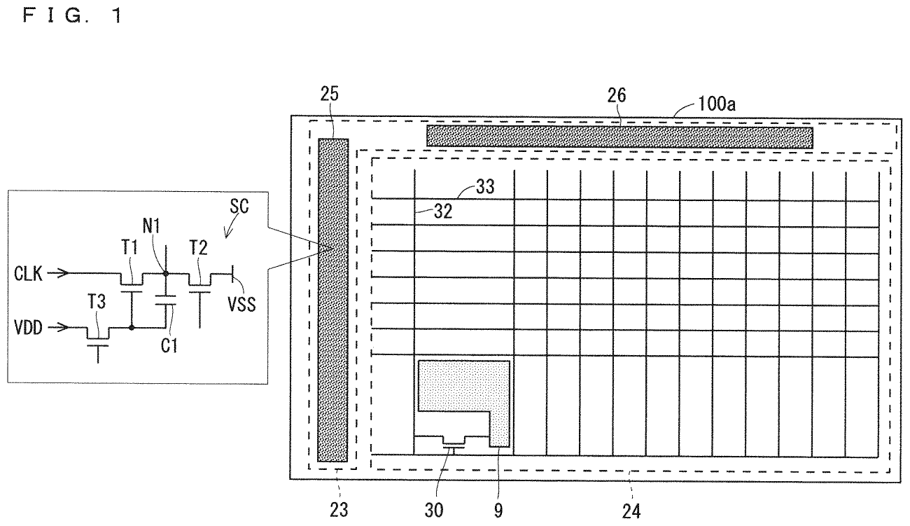

FIG. 1 is a plan view schematically illustrating the entire structure of a relevant TFT substrate 100a. Thin-film transistors (TFTs) are disposed on this relevant TFT substrate 100a. The TFTs are used as, for example, switching devices of pixel units and drive circuit units that are included in flat panel displays such as liquid crystal displays and electroluminescence (EL) displays.

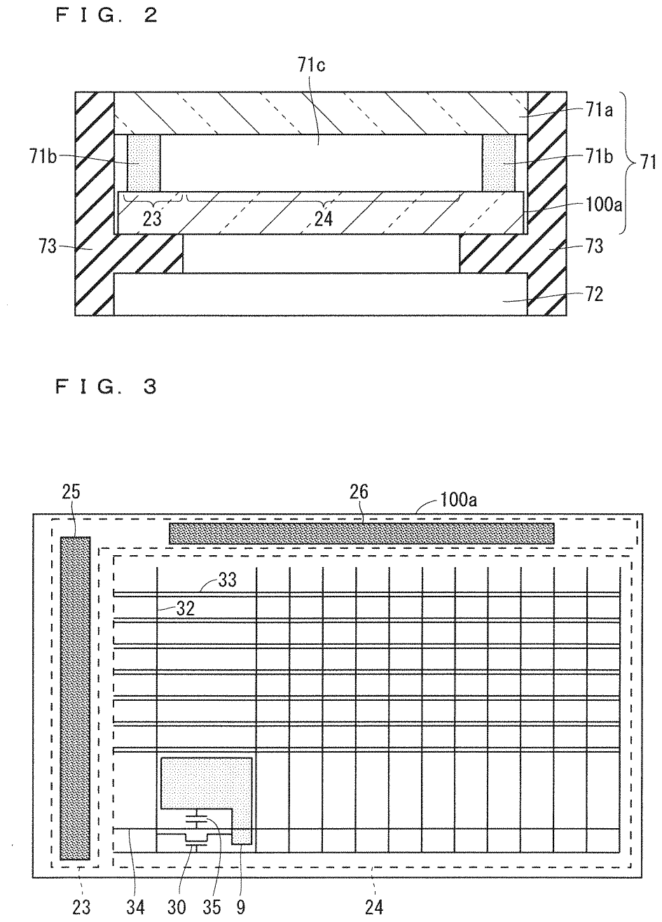

FIG. 2 is a cross section illustrating one example structure of a liquid crystal display. The liquid crystal display in FIG. 2 includes a liquid crystal panel 71, a backlight unit 72, and a frame 73. The liquid crystal panel 71 includes the relevant TFT substrate 100a, a facing substrate 71a, a sealant 71b, a liquid crystal layer 71c, and a driver printed circuit board that is not illustrated. The relevant TFT substrate 100a and the facing substrate 71a are stacked together via the sealant 71b applied to the end portions of these. The liquid crystal layer 71c is sandwiched between the relevant TFT substrate 100a and the facing substrate 71a. The driver printed circuit board is an electronic circuit board for supplying an image signal or drive power, and is also a part connected outside the liquid crystal panel 71.

The frame 73 disposed around the liquid crystal panel 71 holds, as well as the liquid crystal panel 71, the backlight unit 72 disposed opposite to the facing substrate 71a with respect to the relevant TFT substrate 100a. A frame region 23 is defined at the end of the relevant TFT substrate 100a in a plan view. A display region 24 is defined inside of the frame region 23.

A liquid crystal display generally includes a liquid crystal panel (not illustrated) including a TFT substrate 100 and a facing substrate, a driver printed circuit board (not illustrated) connected to this liquid crystal panel, and a backlight unit (not illustrated). The liquid crystal panel has a structure in which a liquid crystal layer is sandwiched between the TFT substrate 100 and the facing substrate. The backlight unit is formed opposite to the facing substrate with respect to the TFT substrate 100, that is, lower than the TFT substrate 100.

As illustrated in FIG. 1, the display region 24 in which pixel units (pixel regions) including pixel TFTs 30 are arranged in a matrix, and the frame region 23 disposed around the display region 24 to enclose the display region 24 are defined in the TFT substrate 100.

The display region 24 includes: a plurality of source lines 32 and a plurality of gate lines 33 orthogonally intersecting each other; and the pixel units each including the pixel TFT 30 and a pixel electrode 9 to correspond to the intersecting portions between the source lines 32 and the gate lines 33.

The frame region 23 includes: a scan signal drive circuit unit 25 that is a drive circuit unit that applies a drive voltage to the gate lines 33; and a display signal drive circuit unit 26 that is a drive circuit unit that applies a drive voltage to the source lines 32. In FIG. 1, the detailed illustration of the connection between the gate lines 33 and the scan signal drive circuit unit 25 and the connection between the source lines 32 and the display signal drive circuit unit 26 is omitted.

The scan signal drive circuit unit 25 sequentially selects the gate lines 33, and applies a gate-ON voltage (drive voltage) to the selected gate lines 33. Consequently, the pixel TFTs 30 connected to the selected gate lines 33 enter the ON state.

The display signal drive circuit unit 26 applies a voltage (drive voltage) to the pixel TFTs 30 in the ON state through the source lines 32. Consequently, the corresponding pixel electrodes 9 store charges through the pixel TFTs 30 in the ON state. The display signal drive circuit unit 26 controls the charges to be supplied to the pixel electrodes 9, according to a gray level of each of the pixel units.

As illustrated in FIG. 1, the scan signal drive circuit unit 25 includes a plurality of drive voltage generating circuit SCs each including drive circuit TFTs (NMOS transistors T1 to T3 herein). A current flows from the drain to the source in each of the drive circuit TFTs in the ON state.

In the drive voltage generating circuit SCs in FIG. 1, a clock signal CLK is given to the drain of the NMOS transistor T1. The source of the NMOS transistor T1 is connected to the drain of the NMOS transistor T2. A ground potential VSS is applied to the source of the NMOS transistor T2. A connection node N1 between the NMOS transistors T1 and T2 is connected to the gate of the NMOS transistor T1 and the source of the NMOS transistor T3 through a capacitor C1. A source potential VDD is applied to the drain of the NMOS transistor T3. The connection node N1 is an output node of the drive voltage generating circuit SC, and applies the drive voltage to the corresponding gate line 33.

When the signal given to the gate of the NMOS transistor T3 turns ON the NMOS transistor T3, the NMOS transistor T1 enters the ON state, and the clock signal CLK is output from the connection node N1. On the other hand, when the signal given to the gate of the NMOS transistor T2 cause the NMOS transistor T2 to enter the ON state, the potential of the connection node N1 is fixed at the ground potential VSS.

When the clock signal CLK has a positive voltage of 20 V and, for example, a positive voltage of approximately 20 V is applied to the gates of the NMOS transistors T1 and T3, the gate line 33 is at the positive voltage of 20 V, and the pixel TFT 30 connected to this gate line 33 enters the ON state. On the other hand, when, for example, the positive voltage of approximately 20 V is applied to the gate of the NMOS transistor T2, the gate line 33 is at the ground potential VSS, and the pixel TFT 30 connected to this gate line 33 enters the OFF state.

Since the display region 24 includes the plurality of gate lines 33, the gate lines 33 are sequentially selected, and the pixel TFTs 30 enter the OFF state. Thus, a proportion of time during which the positive voltage is applied to one of the gate lines 33 for causing the pixel TFT 30 to enter the ON state is approximately 1/(the number of the gate lines 33 in the display region 24). Thus, a proportion of time during which the positive voltage is applied to the gates of the NMOS transistors T1 and T3 is approximately 1/(the number of the gate lines 33 in the display region 24).

On the other hand, causing the pixel TFTs 30 to enter the OFF state requires applying the ground potential VSS to the gate lines 33 connected to the pixel TFTs 30. The ground potential VSS is, for example, −5V.

The time during which the ground potential VSS is applied to one of the gate lines 33 corresponds to the time during which the pixel TFT 30 connected to this gate line 33 enters the OFF state. The proportion of time is approximately 1−1/(the number of the gate lines 33 in the display region 24). Since maintaining the VSS applied state requires causing the NMOS transistor T2 to enter the ON state, the proportion of time during which the positive voltage of approximately 20 V is applied to the gate of the NMOS transistor T2 is approximately 1−1/(the number of the gate lines 33 in the display region 24).

Since the voltage stress to the gate differs between the NMOS transistors T1 to T3 in the scan signal drive circuit unit 25, the electrical characteristics of the drive circuit TFTs (the NMOS transistors T1 to T3) differ, which results in the characteristic fluctuation in, for example, the display of the LCD. Furthermore, since the positive voltage stress applied to the gates of some of the drive circuit TFTs is higher than to those of the pixel TFTs 30, the characteristics of the drive circuit TFTs vary or fluctuate.

Although the positive voltage applied to the gates of the drive circuit TFTs is 20 V in the description above, the positive voltage probably ranges from 10 to 50 V. This increases the margin for the characteristic fluctuation of the drive circuit TFTs. However, the higher the positive voltage becomes, the more the stress to the gates and the characteristic fluctuation of the drive circuit TFTs increase. The voltage that appropriately balances the stress and the characteristic fluctuation is selected as the positive voltage to be applied to the gates of the drive circuit TFTs.

Although the drive voltage generating circuit SC includes the three drive circuit TFTs, the number of the drive circuit TFTs is not limited to this. The drive voltage generating circuit SC may include, for example, more than four drive circuit TFTs to enhance the stability and to reduce the stress by, for example, distributing the time taken for the gate voltage.

Although the detailed description is omitted, the display signal drive circuit unit 26 that applies a voltage to the source lines 32 also includes a plurality of drive voltage generating circuits similarly to the scan signal drive circuit unit 25.

FIG. 3 is a plan view schematically illustrating another overall structure of the relevant TFT substrate 100a. The relevant TFT substrate 100a in FIG. 3 includes common electrode lines 34 and holding capacity electrodes 35 connected to the common electrode lines 34, in addition to the relevant TFT substrate 100a in FIG. 1. The holding capacity electrodes 35 function as assisting holding of the charges in the pixel electrodes 9, and are effective at reducing the leakage of the charges accumulated in the pixel electrodes 9. On the other hand, since the holding capacity electrodes 35 shield the light from the backlight, they have a detrimental effect on decrease in an aperture ratio. Thus, one of the structures in FIGS. 1 and 3 can be selected depending on whether to prioritize the leakage or the aperture ratio.

### Embodiment 1

A structure of a TFT substrate 100 according to Embodiment 1 of the present invention will be described. One example where the TFT substrate 100 according to Embodiment 1 has a general TFT structure referred to as a back-channel etch structure will be hereinafter described.

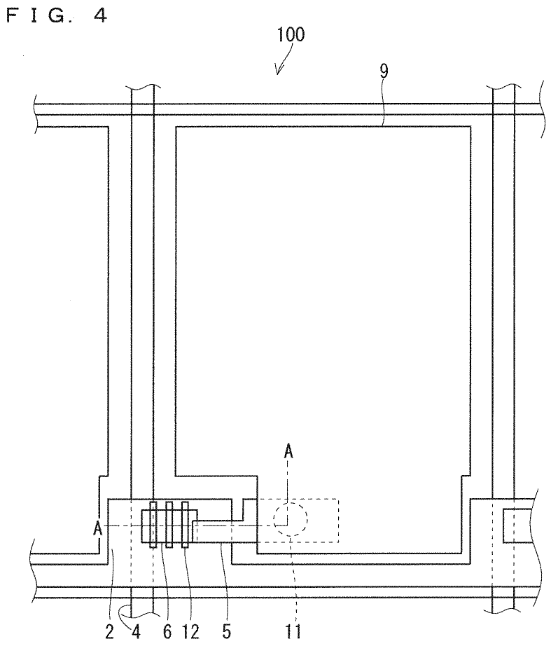

FIG. 4 is a plan view illustrating one example structure of a liquid crystal display including the TFT substrate 100 according to Embodiment 1. FIG. 4 exemplifies a structure of a pixel TFT substrate that is a pixel unit portion of the TFT substrate 100. The TFT substrate 100 in FIG. 4 is a substrate corresponding to the relevant TFT substrate 100a in FIG. 1. As illustrated in FIG. 4, the pixel TFT substrate of the TFT substrate 100 includes a gate electrode 2 that is a part of the gate line 33, a source electrode 4 that is a part of the source line 32, and a drain electrode 5.

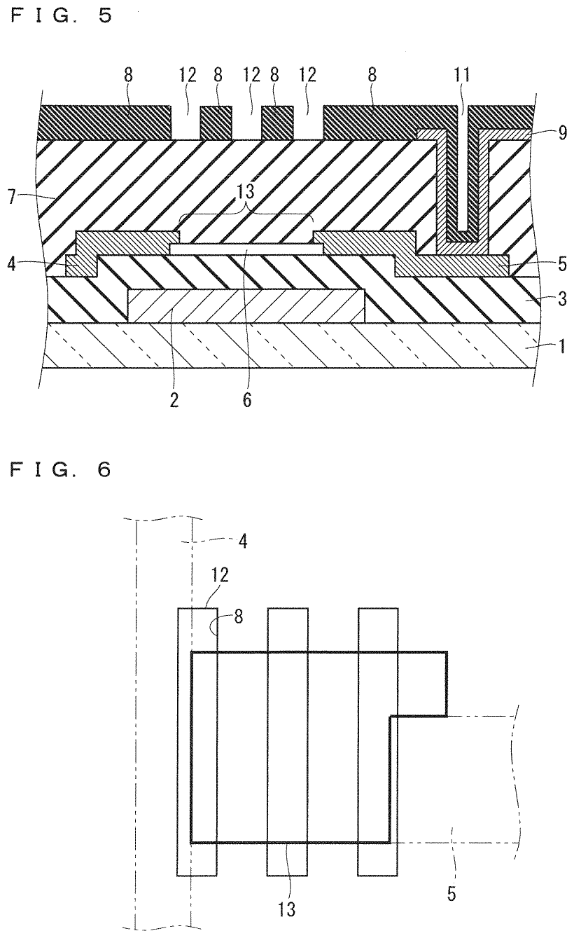

FIG. 5 is a cross section taken along the line A-A of FIG. 4 which illustrates one example structure of the pixel TFT substrate of the TFT substrate 100 according to Embodiment 1.

The TFT substrate 100 includes: a substrate 1; the gate electrode 2 that is the first gate electrode; a gate insulating film 3 that is the first gate insulating film; the source electrode 4 that is the first source electrode; the drain electrode 5 that is the first drain electrode; an oxide semiconductor layer 6 that is the first oxide semiconductor layer; a protective insulating film 7 that is the first protective insulating film; a SiN film 8 that is the first SiN film containing hydrogen; and the pixel electrode 9. Si denotes silicon, and N denotes nitrogen.

The pixel TFT 30 that is a pixel thin film transistor disposed on the substrate 1 includes the gate electrode 2, the gate insulating film 3, the source electrode 4, the drain electrode 5, the oxide semiconductor layer 6, the protective insulating film 7, and the SiN film 8.

The gate electrode 2 is selectively disposed on the substrate 1. The substrate 1 is an insulating substrate having optical transparency, for example, a glass substrate or a quartz substrate. The gate electrode 2 contains a metal such as aluminum. The gate electrode 2 may have a multilayer structure including a material of another composition on both of or either one of the upper and lower surfaces.

The gate insulating film 3 covering the gate electrode 2 is disposed on the substrate 1 and the gate electrode 2. The gate insulating film 3 has a single layer structure including one of insulating materials including, for example, a silicon oxide film, a silicon nitride film, a silicon oxynitride film, and an alumina film, or a multilayer structure including a plurality of these materials.

The oxide semiconductor layer 6 is disposed on the gate insulating film 3, and is superposed on the gate electrode 2 in a plan view. This oxide semiconductor layer 6 functions as a channel of the pixel TFT 30. The oxide semiconductor layer 6 may be made of an oxide semiconductor containing at least one of elements of indium (In), gallium (Ga), and zinc (Zn), for example, an InGaZnO-based oxide semiconductor. The oxide semiconductor layer 6 need not be limited to this but may contain, for example, tin (Sn), aluminum (Al), and boron (B).

The source electrode 4 is disposed on the upper part and the lateral part of one lateral end portion of the oxide semiconductor layer 6, and is connected to the one lateral end portion of the oxide semiconductor layer 6. The drain electrode 5 is disposed on the upper part and the lateral part of the other lateral end portion of the oxide semiconductor layer 6, and is connected to the other lateral end portion of the oxide semiconductor layer 6. The source electrode 4 and the drain electrode 5 are separated from each other on the oxide semiconductor layer 6. The source electrode 4 and the drain electrode 5 contain, for example, a metal such as molybdenum, titanium, or aluminum, or a laminated film of these metals.

The protective insulating film 7 covering the oxide semiconductor layer 6, the source electrode 4, and the drain electrode 5 is disposed on the oxide semiconductor layer 6, the source electrode 4, and the drain electrode 5. The protective insulating film 7 according to Embodiment 1 covers the source electrode 4 and the oxide semiconductor layer 6, and covers the drain electrode 5 except for a contact hole 11 partly disposed on the drain electrode 5. The protective insulating film 7 is disposed to prevent, for example, the water entering from outside, and contains, for example, a silicon oxide film, a silicon nitride film, and alumina.

The pixel electrode 9 that is a transparent electrode and is connected to the drain electrode 5 through the contact hole 11 is disposed on the protective insulating film 7.

The SiN film 8 covering the protective insulating film 7 and containing hydrogen is disposed on the protective insulating film 7. The pixel electrode 9 is disposed under the SiN film 8 according to Embodiment 1. The SiN film 8 plays roles in preventing, for example, the water entering from outside and further insulating a common electrode (not illustrated in FIG. 5) disposed on the SiN film 8 from the pixel electrode 9.

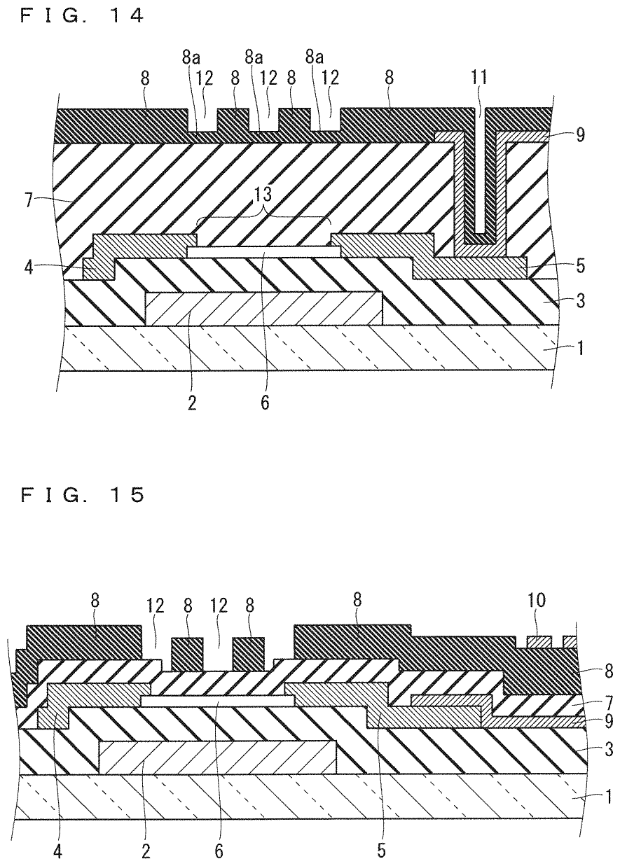

The SiN film 8 includes the first openings that are disposed above at least a part of the first region of the oxide semiconductor layer 6 between the source electrode 4 and the drain electrode 5 in a plan view. The first openings need not always penetrate the SiN film 8, similarly to the structure according to Embodiment 4 to be described later (FIG. 14). In other words, the SiN film 8 may include thinned portions that define the bottom of the first openings.

FIG. 6 is a plan view illustrating first openings 12 disposed above a part of a first region 13 of the oxide semiconductor layer 6 between the source electrode 4 and the drain electrode 5 in a plan view. The first region 13 may be referred to as a “channel 13” because it almost corresponds to the channel of the oxide semiconductor layer 6. As illustrated in FIG. 6, the SiN film 8 does not exist in the first openings 12 disposed above the part of the channel 13.

Here, advantages of the SiN film 8 having the first openings 12 will be described. A negative voltage is applied to the gate of the pixel TFT 30 for a relatively long time. Thus, the negative voltage stress is applied to the oxide semiconductor layer 6 and the gate insulating film 3 almost during the display time. Furthermore, since the light from the backlight is emitted to the TFT, the carriers caused by defects in the oxide semiconductor layer 6 are generated.

The positive charges arising from this generation of the carriers are attracted by the negative voltage stress and trapped to the vicinity of the interface between the gate insulating film 3 and the oxide semiconductor layer 6 near the channel 13 As a result, the electrical characteristics of the TFT fluctuate. Thus, suppressing the defects in the oxide semiconductor layer 6 can suppress the fluctuation of the electrical characteristics.

Here, preventing hydrogen from entering the oxide semiconductor layer 6 is effective at suppressing the defects. The reason is that the hydrogen entering the oxide semiconductor layer 6 cleaves the bond of atoms in the oxide semiconductor layer 6 and becomes a cause of defect creation.

The dominant source of hydrogen is the SiN film 8 whose hydrogen concentration in the TFT structure is the highest and which is relatively closer to the channel 13. In view of this, the first openings 12 of the SiN film 8 are disposed above the channel 13 of the oxide semiconductor layer 6 according to Embodiment 1. Such a structure can suppress the amount of hydrogen supplied to the oxide semiconductor layer 6. As a result, the fluctuation of the electrical characteristics in the pixel TFT 30 can be suppressed. Next, the result of suppressing the fluctuation after application of the stress will be described.

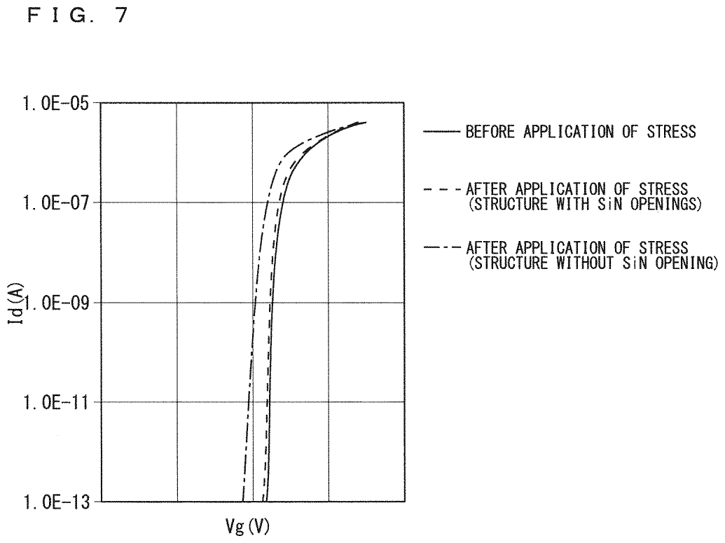

FIG. 7 illustrates the Id-Vg characteristics of the TFT before and after application of the stress according to Embodiment 1 when the horizontal axis represents the gate voltage (Vg) and the vertical axis represents the drain voltage (Id). The characteristics of a structure with the SiN openings (a dotted line in FIG. 7) and the characteristics of a structure without the SiN opening (an alternate long and short dash line in FIG. 7) are illustrated as the characteristics after application of the stress. Since these structures have no substantial difference in the characteristics before application of the stress, the characteristics of only one of the structures (a solid line in FIG. 7) are illustrated.

Here, the structure with the SiN openings is a structure having the first openings 12 without the SiN film 8 above a part of the channel 13. In contrast, the structure without the SiN opening is a structure having the SiN film 8 with a substantially uniform thickness and without having the first openings 12 in the SiN film 8 above the part of the channel 13. The stress means application of a negative voltage to the gate for a long time under light emission.

As illustrated in FIG. 7, the structure without the SiN opening exhibits a relatively larger negative shift of the rising edge of the characteristics after application of the stress than that before application of the stress. In contrast, the structure with the SiN openings hardly exhibits the shift before and after application of the stress. In other words, the structure with the SiN openings suppresses the fluctuation of the electrical characteristics.

As described above, disposing the first openings 12 without the SiN film 8 above the part of the channel 13 can suppress the supply of hydrogen to the channel 13 and stabilize the electrical characteristics of the pixel TFT 30. Moreover, such stabilization is possible without adding a mask to the conventional processes.

The plurality of first openings 12 are preferably arranged uniformly. Furthermore, the first openings 12 are preferably identical in shape. Since these can uniformly suppress the supply of hydrogen from the SiN film 8 to the channel 13, the electrical identification of the pixel TFT 30 can be further stabilized.

Although the first openings 12 are disposed above the part of the channel 13 in FIG. 6, the first openings 12 are not limited to this. For example, the first openings 12 may be disposed above the entire region of the channel 13. This can further suppress the supply of hydrogen to the channel 13.

The larger the first openings 12 of the SiN film 8 become, the more probably the external impurities enter the channel 13 through the first openings 12. Thus, the function of protecting the pixel TFT 30 may be degraded, and the pixel TFT 30 may be deteriorated.

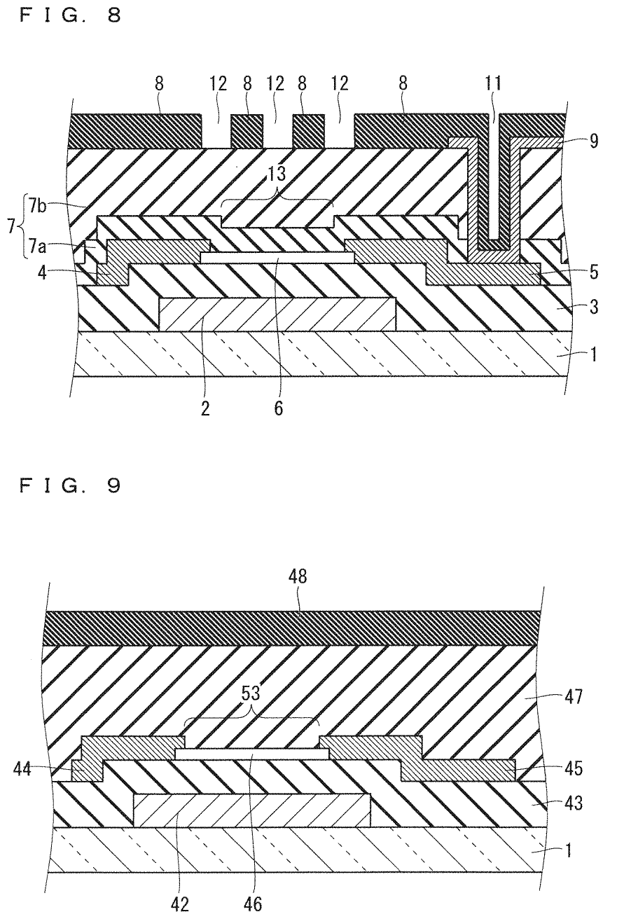

This measure includes a method for improving the protective function of the protective insulating film 7 to be described hereinafter. FIG. 8 is a cross section illustrating one example structure of the pixel TFT substrate including the protective insulating film 7 that is an insulating film of two layers.

The protective insulating film 7 in FIG. 8 includes a low-layer protective insulating film 7a that is a silicon oxide film, and a planarized insulating film 7b disposed on the low-layer protective insulating film 7a. This can make the low-layer protective insulating film 7a into a high-quality film, and improve the protective function of the protective insulating film 7. Moreover, the low-layer protective insulating film 7a can repair the defects on the surface of the channel 13. The high-quality film herein means the low-layer protective insulating film 7a with a relatively higher concentration of oxygen. In other words, the low-layer protective insulating film 7a is higher in concentration of oxygen than the planarized insulating film 7b.

Increase in the concentration of oxygen in the film can make the low-layer protective insulating film 7a into a denser film and suppress the diffusion of impurities. Moreover, this can generate more excess oxygen in the low-layer protective insulating film 7a. This excess oxygen can repair the defects on the surface of the channel 13.

FIG. 9 is a cross section illustrating one example structure of a drive circuit TFT substrate that is a portion of the drive circuit unit of the TFT substrate 100.

The drive circuit TFT substrate of the TFT substrate 100 includes: a gate electrode 42 that is the second gate electrode; a gate insulating film 43 that is the second gate insulating film; a source electrode 44 that is the second source electrode; a drain electrode 45 that is the second drain electrode; an oxide semiconductor layer 46 that is the second oxide semiconductor layer; a protective insulating film 47 that is the second protective insulating film; and a SiN film 48 that is the second SiN film containing hydrogen.

The gate electrode 42 is selectively disposed on the substrate 1. The gate insulating film 43 covers the gate electrode 42. The oxide semiconductor layer 46 is disposed on the gate insulating film 43, and is superposed on the gate electrode 42 in a plan view. The source electrode 44 and the drain electrode 45 are connected to the oxide semiconductor layer 46, and separated from each other on the oxide semiconductor layer 46. The protective insulating film 47 covers the oxide semiconductor layer 46, the source electrode 44, and the drain electrode 45. The SiN film 48 covers the protective insulating film 47. As described above, the drive circuit TFT substrate includes the same constituent elements as those in the pixel TFT substrate. The constituent elements of the drive circuit TFT substrate may be integrated with those of the pixel TFT substrate. For example, the protective insulating film 47 in FIG. 9 may be integrated with the protective insulating film 7 in FIG. 5.

Next, differences between the drive circuit TFT substrate in FIG. 9 and the pixel TFT substrate in FIG. 5 will be described. The gate electrode 42, the gate insulating film 43, the source electrode 44, the drain electrode 45, the oxide semiconductor layer 46, the protective insulating film 47, and the SiN film 48 are included not in the pixel TFT 30 but in the drive circuit TFT that is a drive circuit thin-film transistor disposed on the substrate 1 (for example, the NMOS transistors T1 to T3 in FIG. 1). The SiN film 48 covers an entire second region 53 of the oxide semiconductor layer 46 between the source electrode 44 and the drain electrode 45 in a plan view. The second region 53 may be referred to as a “channel 53” because it almost corresponds to the channel of the oxide semiconductor layer 46.

Here, the gate drive circuit TFT among the drive circuit TFTs is a TFT for controlling the gate voltage of the pixel TFT. As described in the operating principles, a negative voltage is applied to the pixel TFT 30 so that the gate drive circuit TFT controls the gate voltage of the pixel TFT. Conversely, a positive voltage is applied to a part of the gate electrode of the gate drive circuit TFT. Furthermore, the positive voltage is applied to the part of the gate electrode of the gate drive circuit TFT for a longer time than that during which the negative voltage is applied to the pixel TFT 30. Since the positive voltage stress is significantly applied to the gate electrode unlike the pixel TFT 30, the tolerance to the positive voltage stress needs to be improved for the gate drive circuit TFT.

Once electrons attracted by the positive voltage from this positive voltage stress are trapped in the defects in the gate insulating film 43, the characteristics of the gate drive circuit TFT vary or fluctuate. Thus, reduction of the defects in the gate insulating film 43 is necessary to improve the tolerance to the positive voltage stress. The effective way to reduce the defects is to terminate the defects using hydrogen.

In the structure of FIG. 9, the SiN film 48 with the highest hydrogen concentration in the TFT layer structure covers the entire upper surface of the channel 53 in a plan view. Consequently, the hydrogen in the SiN film 48 is effectively supplied to the gate insulating film 43. Thus, the effect of terminating the defects using hydrogen can be enhanced. Since the tolerance to the positive voltage stress to the gates can be improved, the electrical characteristics of the drive circuit TFT can be stabilized.

Although this hydrogen generates defects in the oxide semiconductor layer 46, this encourages the gate voltage threshold to shift to the negative direction in the gate voltage-drain current characteristics of the drive circuit TFT. Since this negative shift of the gate voltage threshold is balanced with the positive shift of the gate voltage threshold with application of the positive voltage stress, the TFT characteristics can be stabilized.

The SiN film 48 need not always cover the entire channel 53. For example, the SiN film 48 in a part of the drive circuit TFT may be disposed above at least a part of the channel 53, and may have the second openings (not illustrated) having a smaller proportion of area to the channel 53 than a proportion of area of the first openings 12 to the channel 13. Since the part of the drive circuit TFT exhibits the positive shift of the gate voltage threshold more significantly than the pixel TFT 30, the positive shift can be suppressed even with this structure. Consequently, the TFT characteristics can be stabilized.

[Manufacturing Method]

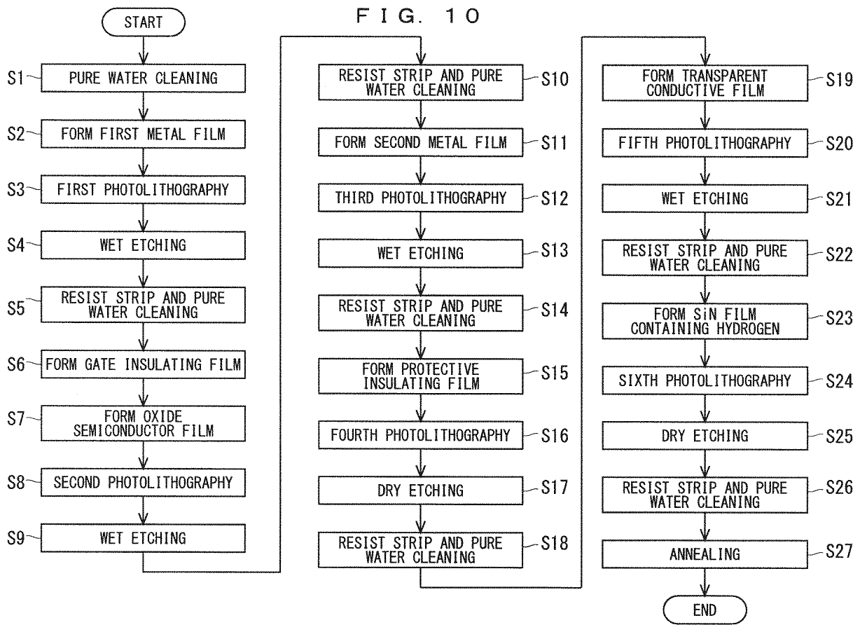

Next, a method for manufacturing the TFT substrate 100 according to Embodiment 1 will be described. Hereinafter, a method for manufacturing the pixel TFT substrate in the TFT substrate 100 will be mainly described. FIG. 10 is a flowchart illustrating one example method for manufacturing the TFT substrate 100 according to Embodiment 1. The resist application and patterning described below are entered as PHOTOLITHOGRAPHY in FIG. 10. The resist removal described below is entered as RESIST STRIP AND PURE WATER CLEANING in FIG. 10.

First, in step S1, the substrate 1 is cleaned with pure water. In step S2, the first metal film made of, for example, aluminum is formed (deposited) on the substrate 1. Then, a resist is applied and patterned in step S3. In step S4, the metal film is wet etched using the resist as a mask to selectively form the gate electrode 2. In step S5, the resist is removed. The thickness of the gate electrode 2 is, for example, approximately 200 nm.

Next, in step S6, the gate insulating film 3 covering the gate electrode 2 on the substrate 1 is formed. The gate insulating film 3 is formed as, for example, a silicon nitride film, a silicon oxide film, an alumina film, or a laminated film of these films by using chemical vapor deposition (CVD) or sputtering. The total film thickness of the gate insulating film 3 is, for example, approximately 200 to 600 nm.

Next, in step S7, an oxide semiconductor film such as an InGaZnO film is formed with a thickness of, for example, approximately 50 nm on the gate insulating film 3 by sputtering. Then, a resist is applied and patterned in step S8. In step S9, the oxide semiconductor film is wet etched using the resist as a mask to form the oxide semiconductor layer 6. In step S10, the resist is removed. The oxide semiconductor layer 6 is superposed on the gate electrode 2 in a plan view.

After the second metal film made of, for example, titanium, aluminum, or molybdenum is formed on the gate insulating film 3 and the oxide semiconductor layer 6 in step S11, a resist is applied and patterned in step S12. Then, in step S13, the metal film is wet etched using the resist as a mask to form the source electrode 4 and the drain electrode 5. Then, the resist is removed in step S14. The source electrode 4 is connected to one side of the oxide semiconductor layer 6, and the drain electrode 5 is connected to the other side of the oxide semiconductor layer 6. The source electrode 4 and the drain electrode 5 are separated from each other on the oxide semiconductor layer 6. Instead of the wet etching, dry etching may be used for the etching for forming the source electrode 4 and the drain electrode 5. Gas species and etchants for the dry etching are appropriately selected according to the material of the source electrode 4, etc.

In step S15, a protective insulating film to be the protective insulating film 7 is formed to cover the surface of the oxide semiconductor layer 6, the source electrode 4, and the drain electrode 5. The protective insulating film is formed by, for example, coating an organic substance including a silicon oxide film by a coating method. A slit coater or a spin coater is used for the coating method. The upper surface of the protective insulating film can be planarized by using the coating method. The protective insulating film may contain an organic film excluding silicon. The film thickness of the organic film is, for example, approximately 1.5 μm. When a photosensitive resin is used as this protective insulating film, the resist application process can be eliminated. As illustrated in the structure of FIG. 8, a silicon oxide film to be the low-layer protective insulating film 7a may be formed by CVD as a lower layer of an insulating film to be the planarized insulating film 7b, before forming the insulating film. The film thickness of the protective insulating film is, for example, approximately 100 nm. Furthermore, the single layer of the silicon oxide film may be used as the protective insulating film.

In step S16, a resist is applied and patterned. In step S17, the protective insulating film on the drain electrode 5 is dry etched using the resist as a mask to form the protective insulating film 7 including the contact hole 11. In step S18, the resist is removed.

In step S19, a transparent conductive film such as an ITO film (a film containing In, Sn, and O) is formed on an inner wall of the contact hole 11 and the protective insulating film 7 by sputtering, etc. Then, a resist is applied and patterned in step S20. In step S21, the ITO film is wet etched to form the pixel electrode 9. Then, the resist is removed in step S22. The materials of the pixel electrode 9 are not limited to the ITO elements, but may be any material with conductive properties for transmission in a visible region such as an oxide semiconductor. The materials may be, for example, InZnO, InO, or ZnO.

In step S23, a SiN film containing hydrogen to be the SiN film 8 is formed on the pixel electrode 9 and the protective insulating film 7 by CVD, etc. SiH₄, NH₃, N₂, etc., are used as source gases. Furthermore, a forming temperature of the SiN film containing hydrogen is preferably a relatively low temperature near 200° C. Furthermore, the forming temperature of the SiN film containing hydrogen is preferably lower than that of the gate insulating film 3. Consequently, the hydrogen contained in the SiN film containing hydrogen can be denser than that contained in the gate insulating film 3.

The hydrogen concentration in the SiN film containing hydrogen is, for example, approximately 3×10²¹ atoms/cm³. Here, the hydrogen concentration of the SiN film containing hydrogen is preferably higher than that of the gate insulating film 3 by setting the hydrogen concentration in the gate insulating film 3 to, for example, approximately 2×10²¹ atoms/cm³. Consequently, the SiN film 8 becomes dominant among the constituent elements that provide hydrogen to the oxide semiconductor layer 6 and the gate insulating film 3, and the effect of hydrogen is easily controlled. Thus, the fluctuation of the electrical characteristics can be further stabilized.

In step S24, a resist is applied and patterned. In step S25, the SiN film containing hydrogen is dry etched to form the SiN film 8 including the first openings 12. Although not illustrated, a contact hole is formed for an external leading terminal portion simultaneously when the SiN film 8 is formed. Thus, the SiN film containing hydrogen above the leading terminal portion is etched. In step S26, the resist is removed. In step S27, annealing is performed. This can reduce the resistance of the pixel electrode 9.

Through these processes, the pixel TFT substrate in FIG. 5 is completed. Although formation of the pixel TFT substrate is described above, the drive circuit TFT substrate in FIG. 9 can be formed through the same processes. In step S24, the SiN film 48 with the second openings or without any opening is formed. The pixel TFT substrate in FIG. 5 and the drive circuit TFT substrate in FIG. 9 may be formed in parallel or sequentially.

### Embodiment 2

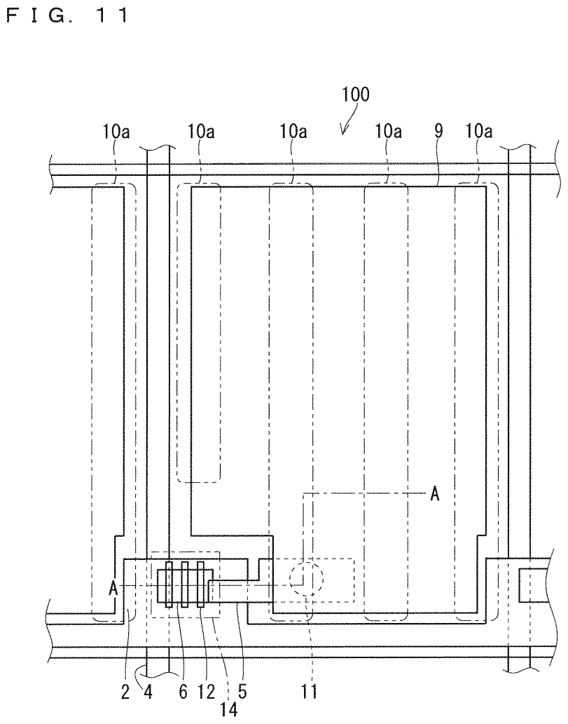

FIG. 11 is a plan view illustrating one example structure of a liquid crystal display including the TFT substrate 100 according to Embodiment 2 of the present invention. FIG. 11 exemplifies a structure of a pixel TFT substrate. FIG. 12 illustrates a cross section taken along the line A-A of FIG. 11. Among the constituent elements according to Embodiment 2, the same or similar constituent elements as those described above will have the same reference numerals, and the different constituent elements will be mainly described. Some of the constituent elements lack dimensional consistency between FIG. 11 and FIG. 12 for illustrative convenience.

As illustrated in FIG. 12, the pixel electrode 9 is electrically connected to the drain electrode 5 and disposed under the SiN film 8 according to Embodiment 2, similarly to Embodiment 1. On the other hand, the structure of FIG. 12 according to Embodiment 2 differs from that of FIG. 5 according to Embodiment 1 in further including a common electrode 10 and a pixel electrode isolated pattern 14 that is a conductive layer.

The common electrode 10 is disposed on the SiN film 8 and above the pixel electrode 9. The common electrode 10 is also disposed on the first openings 12 of the SiN film 8 and above the entire region of the channel 13. The common electrode 10 includes openings 10a where the common electrode 10 does not exist. As illustrated in FIG. 11, the openings 10a are approximately rectangular. The common electrode 10 can produce, with the pixel electrode 9, an electric field passing through, for example, the openings 10a. This electric field can control the orientation of liquid crystals or display characteristics of the liquid crystals.

The pixel electrode isolated pattern 14 is disposed on the protective insulating film 7 and exposed through the first openings 12 of the SiN film 8. The pixel electrode isolated pattern 14 according to Embodiment 2 is disposed above the entire region of the channel 13.

Various materials are selected so that the etching speed of the pixel electrode isolated pattern 14 is lower than that of the SiN film 8. Thus, the pixel electrode isolated pattern 14 functions as an etching stopper that prevents the constituent elements under the pixel electrode isolated pattern 14 from being etched when the first openings 12 are disposed in the SiN film 8 by etching. Thus, disposing the pixel electrode isolated pattern 14 facilitates the process of forming the first openings 12 in the SiN film 8.

The materials and the composition of the pixel electrode isolated pattern 14 are preferably identical to those of the pixel electrode 9. Specifically, the transparent conductive film is preferably used for forming the pixel electrode isolated pattern 14 similarly to forming of the pixel electrode 9. Here, the processes can be simplified by simultaneously forming and patterning the pixel electrode isolated pattern 14 and the pixel electrode 9.

Since disposing the pixel electrode isolated pattern 14 under the SiN film 8 can prevent the hydrogen in the SiN film 8 from diffusing into the channel 13, the characteristics of the pixel TFT can be more stabilized. Moreover, the electrical connection of the common electrode 10 to the pixel electrode isolated pattern 14 can avoid floating of the pixel electrode isolated pattern 14.

[Manufacturing Method]

Next, a method for manufacturing the TFT substrate 100 according to Embodiment 2 will be described. Hereinafter, a method for manufacturing the pixel TFT substrate in the TFT substrate 100 will be mainly described.

After the processes from steps S1 to S19 of FIG. 10 described in Embodiment 1 are performed, the pixel electrode isolated pattern 14 is also formed in steps S20 to S22. In other words, after the protective insulating film 7 is formed, the pixel electrode 9 electrically connected to the drain electrode 5 and the pixel electrode isolated pattern 14 separated from the pixel electrode 9 and located above at least the part of the channel 13 are formed on the protective insulating film 7.

In step S23, the SiN film containing hydrogen to be the SiN film 8 covering the protective insulating film 7, the pixel electrode 9, and the pixel electrode isolated pattern 14 is formed. In step S24, a resist is applied and patterned. In step S25, the SiN film containing hydrogen is etched to form the pixel electrode isolated pattern 14 as the first openings 12. In step S26, the resist is removed.

The common electrode 10 is formed on the SiN film 8 and above the pixel electrode 9 by performing processes similar to steps S19 to S222 between steps S26 and S27. For example, a transparent conductive film such as an ITO film (a film containing In, Sn, and O) is formed by sputtering, etc. Then, a resist is applied and patterned. The ITO film is wet etched to form the common electrode 10. Then, the resist is removed. The common electrode 10 is also formed in the first openings 12, and electrically connected to the pixel electrode isolated pattern 14. Maintaining the pixel electrode isolated pattern 14 at the potential of the common electrode 10 can avoid a floating state of the pixel electrode isolated pattern 14. Consequently, the electrical characteristics of the pixel TFT 30 can be stabilized. Furthermore, when the surface of the common electrode 10 that faces the pixel electrode 9 is formed in a comb-like manner, the liquid crystals can be controlled more efficiently through an electric field produced between these electrodes.

Through the annealing in step S27, the pixel TFT substrate in FIG. 12 is formed.

### Embodiment 3

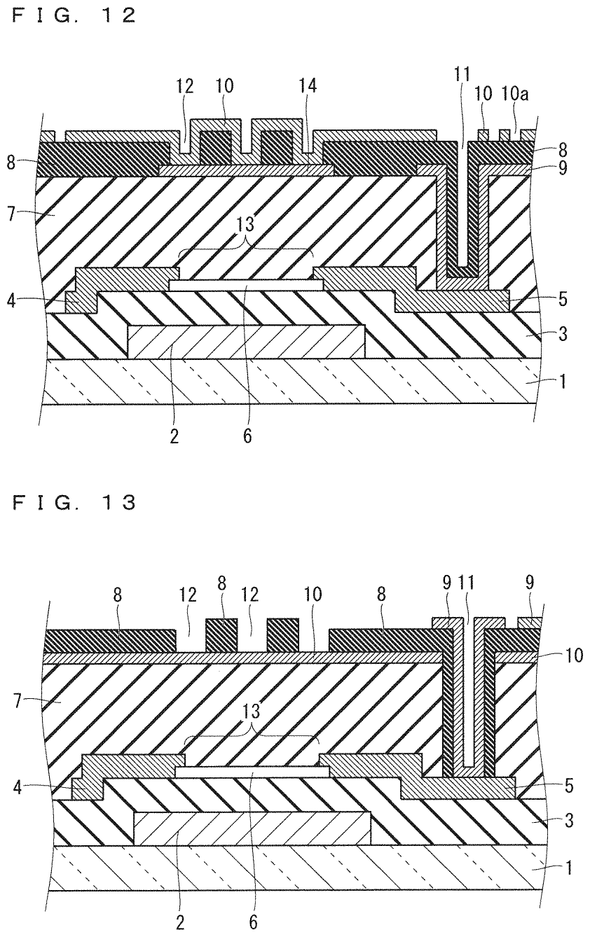

FIG. 13 is a cross section illustrating one example structure of a liquid crystal display including the TFT substrate 100 according to Embodiment 3 of the present invention. FIG. 13 exemplifies a structure of a pixel TFT substrate. Among the constituent elements according to Embodiment 3, the same or similar constituent elements as those described above will have the same reference numerals, and the different constituent elements will be mainly described.

The pixel electrode 9 and the common electrode 10 in the structure of FIG. 13 according to Embodiment 3 are vertically opposite to those in the structure of FIG. 12 according to Embodiment 2. In other words, the pixel electrode 9 is electrically connected to the drain electrode 5 and disposed on the SiN film 8 according to Embodiment 3. The common electrode 10 is disposed under the SiN film 8 and below the pixel electrode 9.

Since the common electrode 10 is disposed under the SiN film 8 in this structure, the common electrode 10 functions as an etching stopper when the first openings 12 are formed. Thus, without the pixel electrode isolated pattern 14, the processes and the formation are facilitated, and the yielding is improved.

### Embodiment 4

FIG. 14 is a cross section illustrating one example structure of a liquid crystal display including the TFT substrate 100 according to Embodiment 4 of the present invention. FIG. 14 exemplifies a structure of a pixel TFT substrate. Among the constituent elements according to Embodiment 4, the same or similar constituent elements as those described above will have the same reference numerals, and the different constituent elements will be mainly described.

The structure of FIG. 14 according to Embodiment 4 differs from that of FIG. 4 according to Embodiment 1 in that the SiN film 8 according to Embodiment 4 includes thinned portions 8a that are thinner than the other portions and these thinned portions 8a define the bottom of the first openings 12.

Such a structure can suppress the amount of hydrogen supplied to the oxide semiconductor layer 6 more than the structure in which the SiN film 8 has the uniform thickness. Consequently, the electrical characteristics of the pixel TFT 30 can be stabilized. The structure with the thinned portions 8a can reduce the probability of entrance of external impurities into the channel 13 through the thinned portions 8a more than the structure without the thinned portions 8a (a structure in which the first openings 12 penetrate the SiN film 8). Thus, the first openings 12 can be enlarged to a certain extent without concern for the probability of entrance of the impurities. The thickness of the thinned portions 8a can be controlled by predetermining an etching rate of the SiN film 8 and a thickness of the SiN film 8 before etching, and managing the etching time based on the etching rate and the thickness.

For example, the SiN film 8 may have a two-layer structure of a lower layer and an upper layer whose hydrogen content is larger than that of the lower layer. Since this structure can increase the etching rate of the upper layer, it is possible to etch almost only the upper layer so that only the lower layer remains or to control the thickness of the thinned portions 8a. Methods for increasing the hydrogen content in the upper layer include a method for reducing the temperature of the upper layer more than that of the lower layer when the SiN film 8 is formed, and a method for irradiating the surface layer of the SiN film 8 with hydrogen plasma after forming the SiN film 8. The etching of the SiN film 8 with the two-layer structure may be not only dry etching but also wet etching using a chemical solution. Since application of the wet etching can easily change the etching rate according to the hydrogen content in the SiN film 8, almost only the upper layer of the SiN film 8 can be selectively etched.

Similarly to the SiN film 8, the SiN film 48 of the drive circuit TFT substrate in FIG. 7 may include thinned portions that define the bottom of the second openings. Here, the thinned portions 8a of the SiN film 8 are preferably thinner than those of the SiN film 48. Consequently, the hydrogen in the SiN film 48 of the drive circuit TFT substrate is effectively supplied to the gate insulating film 43. Thus, the effect of terminating the defects using hydrogen can be enhanced. Since the tolerance to the positive voltage stress to the gates can be improved, the electrical characteristics of the drive circuit TFT substrate can be stabilized.

### Embodiment 5

FIG. 15 is a cross section illustrating one example structure of a liquid crystal display including the TFT substrate 100 according to Embodiment 4 of the present invention. FIG. 15 exemplifies a structure of a pixel TFT substrate. Among the constituent elements according to Embodiment 4, the same or similar constituent elements as those described above will have the same reference numerals, and the different constituent elements will be mainly described.

The common electrode 10 is disposed on the SiN film 8 and above the pixel electrode 9 according to Embodiment 4, similarly to Embodiment 2 (FIG. 12). However, the pixel electrode 9 is disposed not on but under the protective insulating film 7 according to Embodiment 4. In this structure, the pixel electrode 9 is formed after the source electrode 4 and the drain electrode 5 are formed and before the protective insulating film 7 is formed. Since the protective insulating film 7 and the SiN film 8 can be continuously formed, reduction in the number of processes and the cost can be expected.

On the other hand, an aperture ratio as a liquid crystal display characteristic in the structure of FIG. 15 according to Embodiment 4 is lower than that of the FIG. 12 according to Embodiment 2. Thus, one of the structures in FIGS. 12 and 15 can be selected depending on which function is prioritized, namely, reduction in the cost or increase in the aperture ratio.

Within the scope of the present invention, Embodiments can be freely combined, and each of Embodiments can be appropriately modified or omitted.

Although the present invention has been described in detail, the description is in all aspects illustrative and does not restrict the present invention. Therefore, numerous modifications that have not yet been exemplified will be devised without departing from the scope of the present invention.

### EXPLANATION OF REFERENCE SIGNS

1 substrate, 2, 42 gate electrode, 3, 43 gate insulating film, 4, 44 source electrode, 5, 45 drain electrode, 6, 46 oxide semiconductor layer, 7, 47 protective insulating film, 7a low-layer protective insulating film, 7b planarized insulating film, 8, 48 SiN film, 8a thinned portion, 9 pixel electrode, 10 common electrode, 12 first opening, 13, 53 channel, 14 pixel electrode isolated pattern, 30 pixel TFT, 71 liquid crystal panel, 71a facing substrate, 71c liquid crystal layer, 73 backlight unit, 100 TFT substrate, T1 to T3 NMOS transistor.

1. A thin-film transistor substrate, comprising:
a substrate;
a first gate electrode selectively disposed on the substrate;
a first gate insulating film covering the first gate electrode;
a first oxide semiconductor layer disposed on the first gate insulating film and superposed on the first gate electrode in a plan view;
a first source electrode and a first drain electrode that are connected to the first oxide semiconductor layer and separated from each other on the first oxide semiconductor layer;
a first protective insulating film covering the first oxide semiconductor layer, the first source electrode, and the first drain electrode; and
a first SiN film covering the first protective insulating film and containing hydrogen,
wherein the first SiN film includes a first opening disposed above a part of a first region of the first oxide semiconductor layer between the first source electrode and the first drain electrode in the plan view, and
the first SiN film is disposed above the first region excluding the part.

2. The thin-film transistor substrate according to claim 1,
wherein the first SiN film includes a thinned portion thinner than the others, the thinned portion defining a bottom of the first opening.

3. The thin-film transistor substrate according to claim 1, further comprising:
a second gate electrode selectively disposed on the substrate;
a second gate insulating film covering the second gate electrode;
a second oxide semiconductor layer disposed on the second gate insulating film and superposed on the second gate electrode in the plan view;
a second source electrode and a second drain electrode that are connected to the second oxide semiconductor layer and separated from each other on the second oxide semiconductor layer;
a second protective insulating film covering the second oxide semiconductor layer, the second source electrode, and the second drain electrode; and
a second SiN film covering the second protective insulating film and containing hydrogen,
wherein the second SiN film covers an entire second region of the second oxide semiconductor layer between the second source electrode and the second drain electrode in the plan view; or
the second SiN film includes a second opening disposed above at least a part of the second region, the second opening having a smaller proportion of area to the second region than a proportion of area of the first opening to the first region,
the first gate electrode, the first gate insulating film, the first oxide semiconductor layer, the first source electrode, the first drain electrode, the first protective insulating film, and the first SiN film are included in a pixel thin film transistor disposed on the substrate, and
the second gate electrode, the second gate insulating film, the second oxide semiconductor layer, the second source electrode, the second drain electrode, the second protective insulating film, and the second SiN film are included in a drive circuit thin-film transistor disposed on the substrate.

4. The thin-film transistor substrate according to claim 1,
wherein a plurality of the first openings are arranged uniformly.

5. The thin-film transistor substrate according to claim 1, further comprising:
a pixel electrode electrically connected to the first drain electrode and disposed under the first SiN film; and
a common electrode disposed on the first SiN film and above the pixel electrode.

6. The thin-film transistor substrate according to claim 1, further comprising:
a pixel electrode electrically connected to the first drain electrode and disposed on the first SiN film; and
a common electrode disposed under the first SiN film and below the pixel electrode.

7. The thin-film transistor substrate according to claim 1, further comprising:
a pixel electrode electrically connected to the first drain electrode and disposed under the first protective insulating film; and
a common electrode disposed on the first SiN film and above the pixel electrode.

8. The thin-film transistor substrate according to claim 1, further comprising
a conductive layer disposed on the first protective insulating film and exposed through the first opening of the first SiN film.

9. The thin-film transistor substrate according to claim 1,
wherein the first gate insulating film contains hydrogen, and
the hydrogen contained in the first SiN film is denser than the hydrogen contained in the first gate insulating film.

10. The thin-film transistor substrate according to claim 1,
wherein the first protective insulating film includes:
a silicon oxide film; and
a planarized insulating film disposed on the silicon oxide film.

11. A liquid crystal display, comprising:
a liquid crystal panel including the thin-film transistor substrate according to claim 1, a facing substrate, and a liquid crystal layer between the thin-film transistor substrate and the facing substrate; and
a backlight unit disposed opposite to the facing substrate with respect to the thin-film transistor substrate.

12. A method for manufacturing a thin-film transistor substrate, the method comprising:
selectively forming a first gate electrode on a substrate;
forming a first gate insulating film covering the first gate electrode;
forming a first oxide semiconductor layer on the first gate insulating film, the first oxide semiconductor layer being superposed on the first gate electrode in a plan view;
forming a first source electrode and a first drain electrode that are connected to the first oxide semiconductor layer and separated from each other on the first oxide semiconductor layer;
forming a first protective insulating film covering the first oxide semiconductor layer, the first source electrode, and the first drain electrode;
forming a SiN film covering the first protective insulating film and containing hydrogen; and
forming a first opening in the SiN film above a part of a first region of the first oxide semiconductor layer between the first source electrode and the first drain electrode in the plan view,
wherein the SiN film is disposed above the first region excluding the part.

13. The method according to claim 12, comprising:
forming, on the first protective insulating film after forming the first protective insulating film, a pixel electrode electrically connected to the first drain electrode, and a conductive layer separated from the pixel electrode and located above the part of the first region;
forming the SiN film covering the first protective insulating film, the pixel electrode, and the conductive layer; and
forming, as the first opening, an opening exposing the conductive layer.

14. The method according to claim 12,
wherein a forming temperature of the SiN film is lower than a forming temperature of the first gate insulating film.
